(19) United States
(12) Patent Application Publication
(10) Pub. No.: US 2008/0290960 A1
(43) Pub. Date: Nov. 27, 2008

(54) APPARATUS OF IMPEDANCE MATCHING FOR BIDIRECTIONAL DATA LINE

(75) Inventor: Ban Hok Goh, Singapore (SG)

Correspondence Address: SCHWEGMAN, LUNDBERG & WOESSNER / INFINEON, P.O. BOX 2938, MINNEAPOLIS, MN, 55402, US

(73) Assignee: INFINEON TECHNOLOGIES AGAM CAMPEON, 1-12 NEUBIBERG (DE)

(21) Appl. No.: 11/752,489

(22) Filed: May 23, 2007

(51) Int. Cl. H03H 7/38

(52) U.S. Cl. 333/32

(57) ABSTRACT

An apparatus includes a bidirectional data line to couple to a device and an impedance to provide an impedance matching between the data line and the device. In some embodiments, when a direction of data flow in the data line is away from the device, the impedance is of a first impedance value, and when the direction of the data flow is toward the device, the impedance is of a second impedance value. In one embodiment, the second impedance value is substantially zero.

### TECHNICAL FIELD

The various embodiments described herein relate generally to bidirectional signal data lines.

### BACKGROUND

In many situations, for example, in a signal data line, there is a need to avoid or reduce signal distortion of data transmitted over the signal data line. Signal distortion also needs to be avoided or reduced over a bidirectional data line.

### BRIEF DESCRIPTION OF THE DRAWINGS

Some embodiments of the present application are illustrated by way of examples, and not by way of limitations, in the figures of the accompanying drawings in which:

FIGS. 1A and 1B are block diagrams illustrating an apparatus of providing impedance matching between a bidirectional signal data line and a data controller chip respectively for write and read operations in accordance with an embodiment of the present application;

FIGS. 2A and 2B are block diagrams illustrating an apparatus of providing impedance matching between a bidirectional signal data line and a data controller chip respectively for write and read operations in accordance with another embodiment of the present application;

FIGS. 3A and 3B are block diagrams illustrating an apparatus of providing impedance matching between a bidirectional signal data line and a data memory chip respectively for write and read operations in accordance with an embodiment of the present application; and

FIGS. 4A and 4B are block diagrams illustrating an apparatus of providing impedance matching between a bidirectional signal data line and a data memory chip respectively for write and read operations in accordance with another embodiment of the present application.

### DETAILED DESCRIPTION

In the following description, for purposes of explanation, numerous specific details are set forth in order to provide a thorough understanding of example embodiments. It will be evident, however, to one skilled in the art that the embodiments of the application may be practiced without these specific details.

The term “impedance matching” used in the following description denotes a practice of attempting to make the output impedance of a source (e.g., a signal transmitter) equal to the input impedance of a load (e.g., a signal transmission line) to which the source is connected in order to minimize the reflection of a signal caused by the load, thus to reduce the distortion to the signal.

The term “bidirectional signal data line” used in the following description denotes a signal data transmission line coupled to a device (e.g., either a data controller chip or a data memory chip) with two potential signal transmission directions, which depends on the operation (e.g., write or read operation) performed by the device.

According to one embodiment of the present application, an apparatus includes a bidirectional data line to couple to a device, and an impedance to provide an impedance matching between the data line and the device. In some embodiments, when a direction of data flow in the data line is away from the device, the impedance is of a first impedance value, and when the direction of the data flow is toward the device, the impedance is of a second impedance value. In an embodiment, the second impedance value is actually zero.

According to one embodiment of the present application, the device could be either a data controller chip or a data memory chip. When the direction of data flow in the data line is away from the device, the impedance is inserted into the data line in series with the device, however when the direction of data flow is toward the device, the impedance is removed from the data line. In some embodiments, a gate circuit is connected in parallel with the impedance, when the direction of data flow is away from the device, the gate circuit is turned OFF so that the data flow passes through the impedance, and when the direction of data flow is toward the device, the gate circuit is turned ON so that the data flow bypasses the impedance.

According to one embodiment of the present application, an apparatus includes: a bidirectional data line to couple between a first device and a second device, first and second impedances respectively adjacent to the first and the second devices to couple in series to and between the first device and the second device by the data line, and a first gate circuit and a second gate circuit to respectively connect in parallel with the first impedance and the second impedance. When the direction of the data flow is from the first device to the second device, the first gate circuit is turned OFF and the second gate circuit is turned ON so that the data flow passes through the first impedance and bypasses the second impedance. When the direction of the data flow is from the second device to the first device, the first gate circuit is turned ON and the second gate circuit is turned OFF so that the data flow bypasses the first impedance and passes through the second impedance. In some embodiments, the first device is a data controller chip, and the second device is a data memory chip. In some embodiments, the data memory chip is a memory selected from a group consisting of DRAM, SRAM, SDRAM, EEPROM, and flash memory.

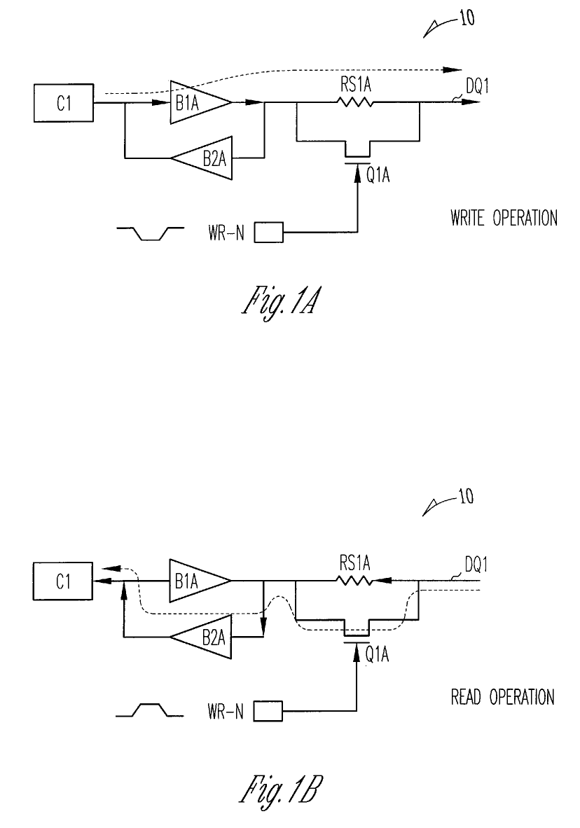

FIGS. 1A and 1B are block diagrams respectively illustrating an apparatus of providing impedance matching between a bidirectional signal data line and a data controller chip respectively for write and read operations in accordance with an embodiment of the present application, in which the write and read operations are controlled by a write/read control signal.

In the embodiment, an apparatus 10 includes a bidirectional data line DQ1 to couple to a data controller chip C1 capable of performing either write or read operation, and an impedance RS1a to provide an impedance matching between the data line DQ1 and the data controller chip C1. Referring to FIG. 1A, when the direction of data flow in the data line DQ1 is away from the data controller chip C1 during write operation, the impedance RS1a is inserted into the data line DQ1 in series with the data controller chip C1 for providing impedance matching therebetween. Referring to FIG. 1B, when the direction of the data flow is toward the data controller chip C1 during read operation, the impedance RS1a is removed from the data line DQ1 since no impedance matching is needed. In some embodiments, the impedance RS1a can be selected from at least one of a passive resistor, an active resistor, a programmable resistor, a passive impedance, an active impedance, and a programmable impedance.

In some embodiments, a gate circuit Q1a is connected in parallel with the impedance RS1a. Referring to FIG. 1A, when the direction of the data flow is away from the data controller chip C1 during write operation, the gate circuit Q1a is turned OFF so that the data flow passes through the impedance RS1a. Referring to FIG. 1B, when the direction of the data flow is toward the data controller chip C1 during read operation, the gate circuit Q1a is turned ON so that the data flow bypasses the impedance RS1a.

In some embodiments, the gate circuit Q1a includes at least one logic element of AND, OR, NOT, NAND, and NOR logic elements. In one embedment, the gate circuit Q1a is controlled by a write/read control signal WR_N as shown in FIGS. 1A and 1B. Referring to FIG. 1A, a low state of the control signal WR_N is held for write operation, which will disable or turn OFF the gate circuit Q1a, thus the data flow passes through the impedance RS1a. Referring to FIG. 1B, a high state of the control signal WR_N is held for read operation, which will enable or turn ON the gate circuit Q1a, thus the data flow bypasses the impedance RS1a. In some embodiments, the state of the control signal WR_N for read operation is actually the negation of the state of the control signal WR_N for write operation.

In some embodiments, the data line DQ1 is coupled to the data controller chip C1 through one of a first buffer B1a and a second buffer B2a. Referring to FIG. 1A, the first buffer B1a operates for the write operation. Referring to FIG. 1B, the second buffer B2a operates for the read operation.

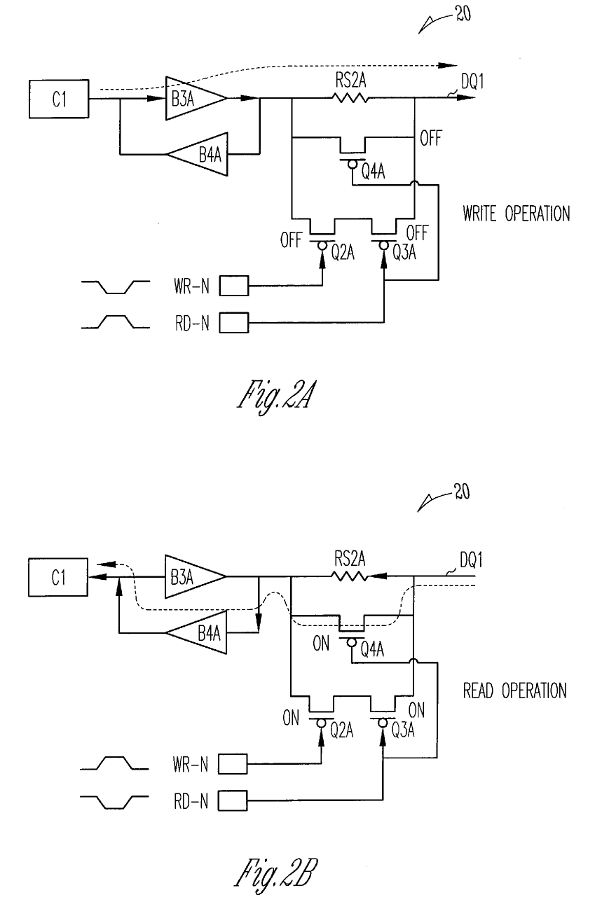

FIGS. 2A and 2B are block diagrams respectively illustrating apparatus of providing impedance matching between a bidirectional signal data line and a data controller chip respectively for write and read operations in accordance with another embodiment of the present application, in which the write or read operation is controlled by separate write and read control signals.

In the embodiment, an apparatus 20 includes a bidirectional data line DQ1 to couple to a data controller chip C1 capable of performing either a write or a read operation, and an impedance RS2a to provide impedance matching between the data line DQ1 and the data controller chip C1. Referring to FIG. 2A, when the direction of data flow in the data line DQ1 is away from the data controller chip C1 during write operation, the impedance RS2a is inserted into the data line DQ1 in series with the data controller chip C1 for providing impedance matching therebetween. Referring to FIG. 2B, when the direction of the data flow is toward the data controller chip C1 during read operation, the impedance RS2a is removed from the data line DQ1 since no impedance matching is needed. In some embodiments, the impedance RS2a can be selected from at least one of a passive resistor, an active resistor, a programmable resistor, a passive impedance, an active impedance, and a programmable impedance.

In some embodiments, a gate circuit is connected in parallel with the impedance RS2a. The gate circuit includes more than one gate (logic elements) selected from AND, OR, NOT, NAND, and NOR logic elements. The gate circuit is controlled by at least two write/read enabling signals. As shown in FIGS. 2A and 2B, for example, the gate circuit includes three gates Q2a, Q3a and Q4a, and is controlled by a write control signal WR_N and a read control signal RD_N.

Referring to FIG. 2A, for a write operation, a LOW state of write control signal WR_N turns OFF the gate Q2a, and a HIGH state of read control signal RD_N turns OFF the gates Q3a and Q4a, thus the impedance RS2a is inserted into the data line DQ1, and the signal data passes through the impedance RS2a. Referring to FIG. 2B, for a read operation, a HIGH state of write control signal WR_N turns ON the gate Q2a, and a LOW state of read control signal RD_N turns ON the gates Q3a and Q4a, thus the impedance RS2a is bypassed and thereby removed from the signal path along the data line DQ1. When both control signals WR_N and RD_N have LOW states, the gates Q4a and Q3a are turned ON, and the gate Q2a is turned OFF, thus the impedance RS2a is bypassed and thereby removed from the signal path along the data line DQ1.

In some embodiments, the data line DQ1 is coupled to data controller chip C1 through one of a first buffer B3a and a second buffer B4a. Referring to FIG. 2A, the first buffer B3a operates for the write operation. Referring to FIG. 2B, the second buffer B4a operates for the read operation.

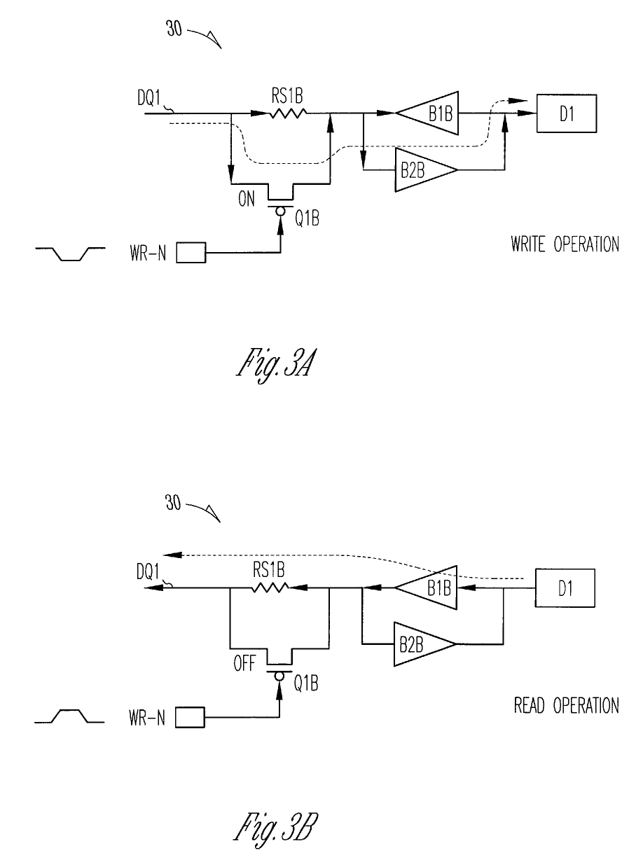

FIGS. 3A and 3B are block diagrams respectively illustrating apparatus of providing impedance matching between a bidirectional signal data line and a data memory chip respectively for write and read operations in accordance with an embodiment of the present application, in which the write and read operations are controlled by a write/read control signal.

In the embodiment, an apparatus 30 includes a bidirectional data line DQ1 to couple to a data memory chip D1 capable of performing either write or read operation, and an impedance RS1a to provide an impedance matching between the data line DQ1 and the data memory chip D1. In some embodiments, the data memory chip D1 is a memory selected from a group consisting of DRAM, SRAM, SDRAM, EEPROM, and flash memory. Referring to FIG. 3A, when the direction of data flow in the data line DQ1 is toward the data memory chip D1 during write operation, the impedance RS1b is removed from the data line DQ1 since no impedance matching is needed. Referring to FIG. 3B, when the direction of the data flow is away from the data memory chip D1 during read operation, the impedance RS1b is inserted into the data line DQ1 in series with the data memory chip D1 for providing impedance matching therebetween. In some embodiments, the impedance RS1b can be selected from at least one of a passive resistor, an active resistor, a programmable resistor, a passive impedance, an active impedance, and a programmable impedance.

In some embodiments, a gate circuit Q1b is connected in parallel with the impedance RS1b. Referring to FIG. 3A, when the direction of the data flow is toward the data memory chip D1 during write operation, the gate circuit Q1b is turned ON so that the data flow bypasses the impedance RS1b. Referring to FIG. 3B, when the direction of the data flow is away from the data memory chip D1 during read operation, the gate circuit Q1b is turned OFF so that the data flow passes through the impedance RS1b.

In some embodiments, the gate circuit Q1b includes at least one logic element of AND, OR, NOT, NAND, and NOR logic elements. In one embodiment, the gate circuit Q1b is controlled by a write/read control signal WR_N as shown in FIGS. 3A and 3B. Referring to FIG. 3A, a low state of the control signal WR_N is held for write operation, which will enable or turn ON the gate circuit Q1b. Referring to FIG. 3B, a high state of the control signal WR_N is held for read operation, which will disable or turn OFF the gate circuit Q1b. In some embodiments, the state of the control signal WR_N for read operation is actually the negation of the state of the control signal WR_N for write operation.

In some embodiments, the data line DQ1 is coupled to the data memory chip D1 through one of a first buffer B1b and a second buffer B2b. Referring to FIG. 3A, the second buffer B2b operates for the data flow toward the data memory chip D1 during write operation. Referring to FIG. 3B, the first buffer B1a operates for the data flow away from the data memory chip D1 during read operation.

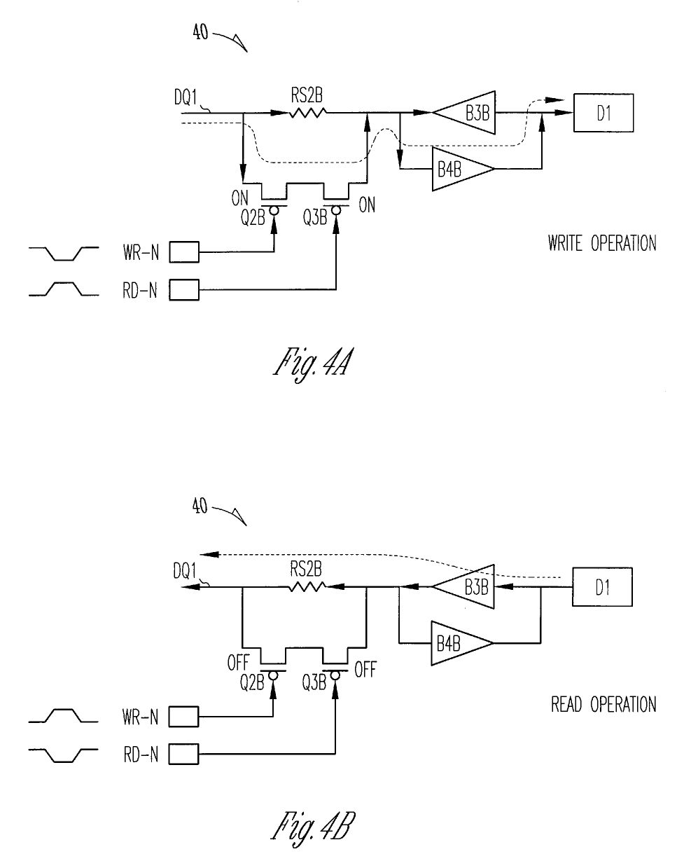

FIGS. 4A and 4B are block diagrams respectively illustrating apparatus of providing impedance matching between a bidirectional signal data line and a data memory chip respectively for write and read operations in accordance with another embodiment of the present application, in which the write or read operation is controlled by separate write and read control signals.

In the embodiment, an apparatus 40 includes a bidirectional data line DQ1 to couple to a data memory chip D1 capable of performing either write or read operation, and an impedance RS2b to provide an impedance matching between the data line DQ1 and the data memory chip D1. In some embodiments, the data memory chip D1 is a memory selected from a group consisting of DRAM, SRAM, SDRAM, EEPROM, and flash memory. Referring to FIG. 4A, when the direction of data flow in the data line DQ1 is toward the data memory chip D1 during write operation, the impedance RS2b is removed from the data line DQ1 since no impedance matching is needed. Referring to FIG. 4B, when the direction of the data flow is away from the data memory chip D1 during read operation, the impedance RS2b is inserted into the data line DQ1 in series with the data memory chip D1 for providing impedance matching therebetween. In some embodiments, the impedance RS2b can be selected from at least one of a passive resistor, an active resistor, a programmable resistor, a passive impedance, an active impedance, and a programmable impedance.

In some embodiments, a gate circuit is connected in parallel with the impedance RS2b. The gate circuit includes more than one gates (logic elements) selected from AND, OR, NOT, NAND, and NOR logic elements, and the gate circuit is controlled by more than one write/read enabling signals. In an embodiment, as shown in FIGS. 4A and 3B, the gate circuit includes two gates Q2b and Q3b, and the gate circuit is controlled by two separate write and read control signals WR_N and RD_N. Referring to FIG. 4A, during write operation, a low state of write control signal WR_N is held to turn ON the gate Q2b, and a high state of read control signal RD_N is held to turn ON the gates Q3b, thus the impedance RS2b is removed from the data line DQ1, and signal data is allowed to bypass the impedance RS2b. Referring to FIG. 4B, during read operation, a high state of write control signal WR_N is held to turn OFF the gate Q2b, and a low state of read control signal RD_N is held to turn OFF the gate Q3b, thus the impedance RS2b is inserted into the data line DQ1, and signal data is allowed to pass through the impedance RS2b.

In some embodiments, the data line DQ1 is coupled to data memory chip D1 through one of a first buffer B3b and a second buffer B4b. Referring to FIG. 4A, the second buffer B4b operates for the data flow toward the data memory chip D1 during write operation. Referring to FIG. 4B, the first buffer B3b operates for the data flow away from the data memory chip D1 during read operation.

The embodiments of the application provides a flexible way of providing impedance matching between a source and a bidirectional signal data line, thus based on the signal flow, it will automatically enable a series resistor for the transmitter end, and disable the series resistor for the receiver end to reduce distortion of the signal.

The accompanying drawings that form a part hereof show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. § 1.72(b), requiring an abstract that will allow the reader to quickly ascertain the nature of the technical disclosure. It is submitted with the understanding that it will not be used to interpret or limit the scope or meaning of the claims.

1. Apparatus, comprising:
a bidirectional data line to couple to a device; and
an impedance to provide impedance matching between the data line and the device, when a direction of data flow in the data line is away from the device, the impedance is of a first impedance value, and when the direction of the data flow is toward the device, the impedance is of a second impedance value.

2. The apparatus of claim 1, wherein the second impedance value is about zero.

3. The apparatus of claim 1, wherein when the direction of data flow in the data line is away from the device, the impedance is inserted into the data line in series with the device, and when the direction of the data flow is toward the device, the impedance is bypassed.

4. The apparatus of claim 1, further comprising a gate circuit connected in parallel with the impedance.

5. The apparatus of claim 4, wherein when the direction of the data flow is away from the device, the gate circuit is turned OFF so that the data flow passes through the impedance.

6. The apparatus of claim 4, wherein when the direction of the data flow is toward the device, the gate circuit is turned ON so that the data flow bypasses the impedance.

7. The apparatus of claim 4, wherein the gate circuit comprises at least one logic element selected from the group consisting of AND, OR, NOT, NAND, and NOR logic elements.

8. The apparatus of claim 1, wherein the data line is coupled to the device through one of first and second buffers, the first buffer operates for the data flow away from the device, and the second buffer operates for the data flow toward the device.

9. The apparatus of claim 1, wherein the impedance comprises at least one of a passive resistor, an active resistor, a programmable resistor, a passive impedance, an active impedance, and a programmable impedance.

10. The apparatus of claim 1, wherein the device is a device selected from a group consisting of a data controller chip and a data memory chip.

11. The apparatus of claim 10, wherein the data memory chip is a memory selected from a group consisting of DRAM, SRAM, SDRAM, EEPROM, and flash memory.

12. The apparatus of claim 1, wherein the device is capable of performing an operation selected from a group consisting of a read operation and a write operation.

13. Apparatus, comprising:
a bidirectional data line to couple to a device;
an impedance to couple in series between the device and the data line; and
a gate circuit to connect in parallel with the impedance, to turn the gate circuit OFF when a direction of data flow in the data line is away from the device so that the data flow passes through the impedance, and to turn the gate circuit ON when the direction of the data flow is toward the device so that the data flow bypasses the impedance.

14. The apparatus of claim 13, wherein the data line is coupled to the device through one of a first buffer and a second buffer, the first buffer operates for the data flow away from the device, and the second buffer operates for the data flow toward the device.

15. The apparatus of claim 13, wherein the impedance comprises at least one of a passive resistor, an active resistor, a programmable resistor, a passive impedance, an active impedance, and a programmable impedance.

16. The apparatus of claim 13, wherein the device is selected from a group consisting of a data controller chip and a data memory chip.

17. The apparatus of claim 13, wherein the device is capable of performing one operation selected from a group consisting of read operation and write operation.

18. An apparatus, comprising:
a bidirectional data line to couple between a first device and a second device;
a first impedance and a second impedance to couple in series with the data line between the first device and the second device, the first impedance and the second impedance being respectively coupled at one end to the first device and the second device; and
a first gate circuit and a second gate circuit to respectively connect in parallel with the first impedance and the second impedance, when the direction of the data flow is from the first device to the second device, to turn the first gate circuit OFF and to turn the second gate circuit ON so that the data flow passes through the first impedance and bypasses the second impedance, and when the direction of the data flow is from the second device to the first device, to turn the first gate circuit ON and to turn the second gate circuit OFF so that the data flow bypasses the first impedance and passes through the second impedance.

19. The apparatus of claim 18, wherein one end of the first impedance is coupled to the first device through one of a first buffer and a second buffer, the first buffer operates for the data flow away from the first device, and the second buffer operates for the data flow toward the first device, and one end of the second impedance is coupled to the second device through one of a third buffer and a fourth buffer, the third buffer operates for the data flow away from the second device, and the fourth buffer operates for the data flow toward the second device.

20. The apparatus of claim 18, wherein each impedance comprises at least one of a passive resistor, an active resistor, a programmable resistor, a passive impedance, an active impedance, and a programmable impedance.

21. The apparatus of claim 18, wherein the first device is a data controller chip.

22. The apparatus of claim 18, wherein the second device is a data memory chip.
